(19) United States
(12) Patent Application Publication
(10) Pub. No.: US 2025/0351313 A1
(43) Pub. Date: Nov. 13, 2025

(54) SYSTEM AND APPARATUS FOR A FLUIDIC HEAT EXCHANGER INCLUDING VENTURI FLOW CHANNELS

(71) Applicant: GM GLOBAL TECHNOLOGY OPERATIONS LLC, Detroit, MI (US)

(72) Inventors: Yilun Luo, Ann Arbor, MI (US); Ronald O. Grover, JR., Northville, MI (US); Mohamed Kamel, Birmingham, MI (US); Chandra S. Namuduri, Troy, MI (US); Song He, Troy, MI (US)

(73) Assignee: GM GLOBAL TECHNOLOGY OPERATIONS LLC, Detroit, MI (US)

(21) Appl. No.: 18/659,344

(22) Filed: May 9, 2024

(51) Int. Cl. H05K 7/20; F28D 21/00; F28F 3/02

(52) U.S. Cl. CPC H05K 7/209; F28F 3/022; F28F 3/025; F28D 2021/0028

(57) ABSTRACT

A fluidic heat exchanger includes a first plate, an inlet port, an outlet port, and a plurality of flow dividers. The flow dividers are arranged orthogonal to the first plate and are arranged in parallel between the inlet port and the outlet port. The flow dividers and the first plate form a plurality of venturi flow channels that are arranged in parallel. The flow dividers are arranged into flow divider pairs, with a first of the flow dividers having a first surface defining a first waveform, and a second of the flow dividers having a second surface defining a second waveform. The second surface is symmetrically opposed to the first surface along a longitudinal axis. This arrangement defines the venturi flow channel, with the flow restriction elements and the expansion chambers being alternatingly arranged in series between the inlet port and the outlet port.

### INTRODUCTION

Power electronic devices, such as may be employed in the operation and control of electric motor/generators, generate heat during operation. Thermal management systems including heat sinks are deployed on the power electronic devices to transfer and remove heat. This may include ambient air-based systems or fluidic circuits that are coupled to a second heat exchanger, e.g., an air/fluid radiator. Fluidic circuits on heat sinks may include meandering flow channels, which have thermal and flow inefficiencies due to pressure drops, flowrates, etc. There are also trade-offs between flowrate and pressure drop. By way of example, an increased coolant flow rate may reduce the thermal resistance and therefore decrease power device temperature. However, a higher flow rate may increase pressure drop, adding load and output power for a coolant pump, thus increasing electric power load and decreasing efficiency of such a system.

### SUMMARY

The concepts described herein relate to a system, apparatus, and/or method related to a novel fluidic heat exchanger, a cooling system for a solid state electronic power module, and an electrified drivetrain of a vehicle having a fluidic cooling circuit that incorporates the fluidic heat exchanger.

An aspect of the disclosure may include a fluidic heat exchanger that includes a first plate, a second plate, an inlet port, an outlet port, and a plurality of flow dividers. The first plate is thermally couplable to a heat source; the plurality of flow dividers are arranged orthogonal to the first plate and are arranged orthogonal to the second plate; the plurality of flow dividers are arranged in parallel between the inlet port and the outlet port; the plurality of flow dividers, the first plate, and the second plate form a plurality of venturi flow channels that are arranged in parallel between the inlet port and the outlet port; the plurality of flow dividers are arranged into a plurality of flow divider pairs, each flow divider pair including a first of the plurality of flow dividers and a second of the plurality of flow dividers; the first of the plurality of flow dividers includes a first surface defining a first waveform; the second of the plurality of flow dividers includes a second surface defining a second waveform; the second surface is symmetrically opposed to the first surface along a longitudinal axis defined between the inlet port and the outlet port; the second surface being symmetrically opposed to the first surface defines a plurality of flow restriction elements and a plurality of expansion chambers in the venturi flow channel; and the plurality of flow restriction elements and the plurality of expansion chambers are alternatingly arranged in series between the inlet port and the outlet port.

Another aspect of the disclosure may include a plurality of pins being affixed to and projecting orthogonally from the first plate, wherein the plurality of pins are disposed in the plurality of expansion chambers.

Another aspect of the disclosure may include each of the plurality of pins being cylindrically shaped.

Another aspect of the disclosure may include each of the plurality of pins being frustoconically shaped.

Another aspect of the disclosure may include each of the plurality of pins being fabricated from a thermally conductive material.

Another aspect of the disclosure may include the plurality of pins being affixed to the second plate.

Another aspect of the disclosure may include the first waveform being defined by the first flow divider as a sinusoidal waveform, and the second waveform being defined by the second waveform as a sinusoidal waveform.

Another aspect of the disclosure may include the first waveform being defined by the first flow divider as a trapezoidal waveform, and the second waveform being defined by the second waveform as a trapezoidal waveform.

Another aspect of the disclosure may include the first plate being formed from a thermally conductive material.

Another aspect of the disclosure may include the second plate being fabricated from a thermally conductive material.

Another aspect of the disclosure may include the second plate being fabricated from a thermally insulative material.

Another aspect of the disclosure may include each of the plurality of flow dividers being fabricated from a thermally conductive material.

Another aspect of the disclosure may include the plurality of flow dividers being arranged in parallel and in parallel to a longitudinal axis defined between the inlet port and the outlet port.

Another aspect of the disclosure may include the plurality of flow dividers being arranged in parallel and arranged transverse to a longitudinal axis defined between the inlet port and the outlet port.

Another aspect of the disclosure may include a cooling system for a solid state electronic power module that includes a fluidic circuit having an embodiment of the fluidic heat exchanger, a pump, a radiator, and a sump, wherein the fluidic circuit contains a heat transfer fluid.

Another aspect of the disclosure may include an electrified drivetrain for a vehicle that includes a DC power source, a multi-phase power inverter, a multi-phase rotary electric machine, a torque actuator, and a cooling system, wherein the multi-phase power inverter includes a solid state electronic power module. A fluidic circuit including an embodiment of the fluidic heat exchanger, a pump, a radiator, and a sump, wherein the fluidic circuit contains a heat transfer fluid.

The above features and advantages, and other features and advantages, of the present teachings are readily apparent from the following detailed description of some of the best modes and other embodiments for carrying out the present teachings, as defined in the appended claims, when taken in connection with the accompanying drawings.

### BRIEF DESCRIPTION OF THE DRAWINGS

One or more embodiments will now be described, by way of example, with reference to the accompanying drawings, in which:

FIG. 1 schematically illustrates an electrified drivetrain having a multi-phase electric machine, a DC power source, a power inverter, and a fluidic heat exchanger, in accordance with the present disclosure.

FIG. 2 schematically illustrates a heat exchange system thermally coupled to a power module of a power inverter, in accordance with the disclosure.

FIGS. 3A, 3B, 3C, and 3D schematically illustrate cutaway side views of a power module and a fluidic heat exchanger, in accordance with the disclosure.

FIG. 4 schematically illustrates an isometric cutaway view of an embodiment of the fluidic heat exchanger including a plurality of venturi flow channels that are formed between flow dividers, in accordance with the disclosure.

FIG. 5 schematically illustrates an isometric cutaway view of another embodiment of the fluidic heat exchanger including a plurality of venturi flow channels that are formed between flow dividers, in accordance with the disclosure.

FIG. 6 schematically illustrates an isometric cutaway view of another embodiment of the fluidic heat exchanger including a plurality of venturi flow channels that are formed between flow dividers, in accordance with the disclosure.

FIG. 7 schematically illustrates a cutaway plan view of an embodiment of a fluidic heat exchanger having a transverse flow axis, in accordance with the disclosure.

FIG. 8 schematically illustrates a cutaway plan view of an embodiment of the fluidic heat exchanger having a longitudinal flow axis, in accordance with the disclosure.

The appended drawings are not necessarily to scale, and present a somewhat simplified representation of various features of the present disclosure as disclosed herein, including, for example, specific dimensions, orientations, locations, and shapes. Details associated with such features will be determined in part by the particular intended application and use environment.

### DETAILED DESCRIPTION

The components of the disclosed embodiments, as described and illustrated herein, may be arranged and designed in a variety of different configurations. Thus, the following detailed description is not intended to limit the scope of the disclosure, as claimed, but is merely representative of possible embodiments thereof. In addition, while numerous specific details are set forth in the following description to provide a thorough understanding of the embodiments disclosed herein, some embodiments may be practiced without some of these details. Moreover, for the purpose of clarity, certain technical material that is understood in the related art has not been described in detail to avoid unnecessarily obscuring the disclosure. Furthermore, the disclosure, as illustrated and described herein, may be practiced in the absence of an element that is not specifically disclosed herein.

The present disclosure is susceptible of embodiment in many different forms. Representative examples of the disclosure are shown in the drawings and described herein in detail as non-limiting examples of the disclosed principles. To that end, elements and limitations described herein, but not explicitly set forth in the claims, are not to be incorporated into the claims, singly or collectively, by implication, inference, or otherwise.

For purposes of the present description, unless specifically disclaimed, use of the singular includes the plural and vice versa, the terms “and” and “or” shall be both conjunctive and disjunctive, and the words “including,” “containing,” “comprising,” “having,” and the like shall mean “including without limitation.” Moreover, words of approximation such as “about,” “almost,” “substantially,” “generally,” “approximately,” etc., may be used herein in the sense of “at, near, or nearly at,” or “within 0-5% of,” or “within acceptable manufacturing tolerances,” or logical combinations thereof.

As used herein, the term “system” refers to mechanical and electrical hardware, software, firmware, electronic control componentry, processing logic, and/or processor device, individually or in combination, including without limitation: application specific integrated circuit (ASIC), an electronic circuit, a processor (shared, dedicated, or group) that executes one or more software or firmware programs, memory device(s) that electrically store software or firmware instructions, a combinatorial logic circuit, and/or other components that provide the described functionality.

As employed herein, terms such as “vertical”, “horizontal”, “left”, “right”, “upper”, “lower”, “top”, “bottom” and similar expressions are non-limiting terms that merely describe the various elements as illustrated in the Figures, and are not intended to limit the scope of the disclosure.

As used herein, the term “electric machine” refers to an electric motor/generator device including a rotor and a stator that is capable of converting electric power to mechanical power and/or converting mechanical power to electric power by electromagnetic effort.

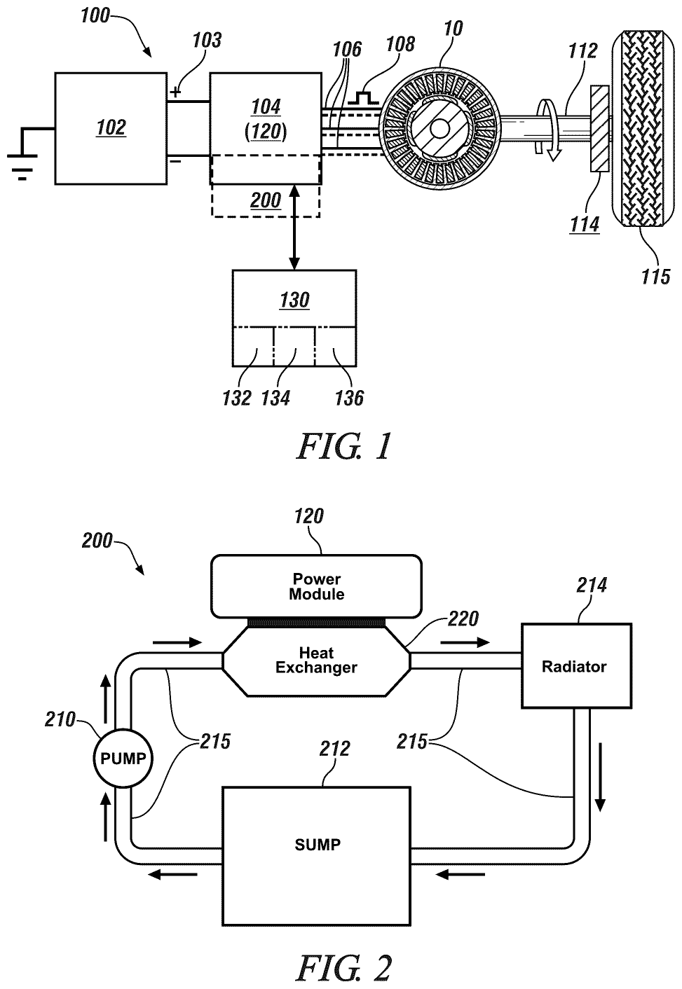

Referring to the drawings, wherein like reference numbers refer to the same or like components in the several Figures, FIG. 1 schematically illustrates elements of an electrified drivetrain 100 that is composed of a DC power source 102, a multi-phase power inverter 104, a multi-phase rotary electric motor/generator (electric machine) 10, and a torque actuator 115, the operations of which are monitored and controlled by a controller 130. Elements of a heat exchange system 200 are thermally coupled to elements of the multi-phase power inverter 104.

In one embodiment, the electrified drivetrain 100 is arranged to generate and transfer torque to torque actuator 115, which may be in the form of one or multiple drive wheels to effect work, e.g., propulsion, when employed on a vehicle. Controller 130 executes control routines to control and manage operation of the multi-phase power inverter 104. In one embodiment, the electrified drivetrain 100 is disposed on a vehicle, and capable of generating tractive torque for vehicle propulsion. When disposed on a vehicle, the vehicle may include, but not be limited to a mobile platform in the form of a commercial vehicle, industrial vehicle, agricultural vehicle, passenger vehicle, aircraft, watercraft, train, all-terrain vehicle, personal movement apparatus, robot and the like to accomplish the purposes of this disclosure. Non-limiting examples of vehicles that employ electrified drivetrains 100 include electric vehicles (EVs) and various hybrid-electric vehicles (HEVs). Alternatively, the electrified drivetrain 100 may be an element of a stationary system.

The controller 130 may be embodied as one or more digital computing devices, and may include one or more processors 134 and memory 132. A control routine 136 may be stored as an executable instruction set in the memory 132 and executed by one of the processors 134 of the controller 130. The controller 130 is in communication with the multi-phase power inverter 104 to control operation thereof in response to execution of the control routine 136 to operate the electric machine 10.

The electric machine 10 includes a cylindrically-shaped rotor assembly arranged on a rotor shaft and disposed within an annularly-shaped stator, wherein the rotor assembly is coaxial with a rotor opening that is formed in the stator. Other elements of the electric machine may include, e.g., end caps, shaft bearings, electrical connections, etc. Electrical windings of the stator are arranged with a quantity of electrical phases and a quantity of electrical turns per phase. Depending on the specific arrangement, the quantity of electrical phases may be between 3 and 6, and the quantity of layers of conductors may be between 4 and 12. In one embodiment, the electric machine 10 is an interior permanent magnet (IPM) device.

The multi-phase power inverter 104 includes one or a plurality of power modules 120 that are adjacent to and thermally coupled to elements of the heat exchange system 200. Each power module 120 is composed using a plurality of semiconductor switches that are arranged and controllable to transform DC electric power to AC electric power, and transform AC electric power to DC electric power, employing a pulse-width modulation signal 108 or another control technique. The multi-phase power inverter 104 is arranged and is controllable to transform DC electric power originating from the DC power source 102 to AC electric power to actuate the electric machine 10 via electromagnetic effort. The electric machine 10 is controllable to rotate and generate mechanical torque that is transferred via a rotatable member 112 and a geartrain 114 to the torque actuator 115 when operating in a torque generating mode. The electric machine 10 is controllable to generate AC electric power from mechanical torque originating at the torque actuator 115 via electromagnetic effort, which is transformed by the multi-phase power inverter 104 to DC electric power for storage in the DC power source 102 when operating in an electric power generating mode. The torque actuator 115 includes, in one embodiment, a vehicle wheel that transfers torque to a ground surface to effect forward motion as part of a traction propulsion system.

The DC power source 102 may be a rechargeable electrochemical battery device, a fuel cell, an ultracapacitor, and/or another electrical energy storage/generation technology. The DC power source 102 connects to the multi-phase power inverter 104 via a high-voltage DC bus 103, and the multi-phase power inverter 104 connects to the electric machine 10 via a plurality of electrical power lines 106.

FIG. 2 schematically illustrates an embodiment of elements of the heat exchange system 200, which is integrated into the plurality of power modules 120 of the multi-phase power inverter 104 that is described with reference to FIG. 1. A single one of the power modules 120 is shown, for purposes of illustrating the concepts described herein.

The heat exchange system 200 includes a fluidic circuit that is composed with a fluidic pump 210, sump 212, air/fluid heat exchanger (radiator) 214, and an embodiment of a fluidic heat exchanger 220, which are fluidly coupled in a closed circuit via conduits 215. A heat transfer fluid, or coolant, composed of water, ethylene glycol, and/or other thermally conductive fluidic material, circulates therein. An embodiment of the fluidic heat exchanger 220 is thermally coupled to one of the power modules 120.

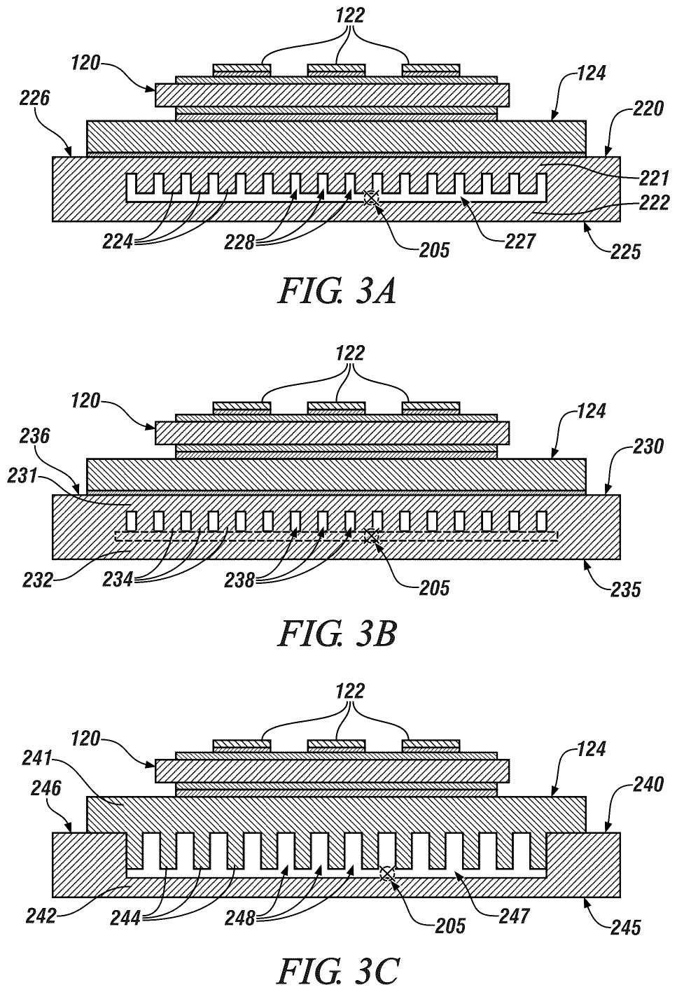

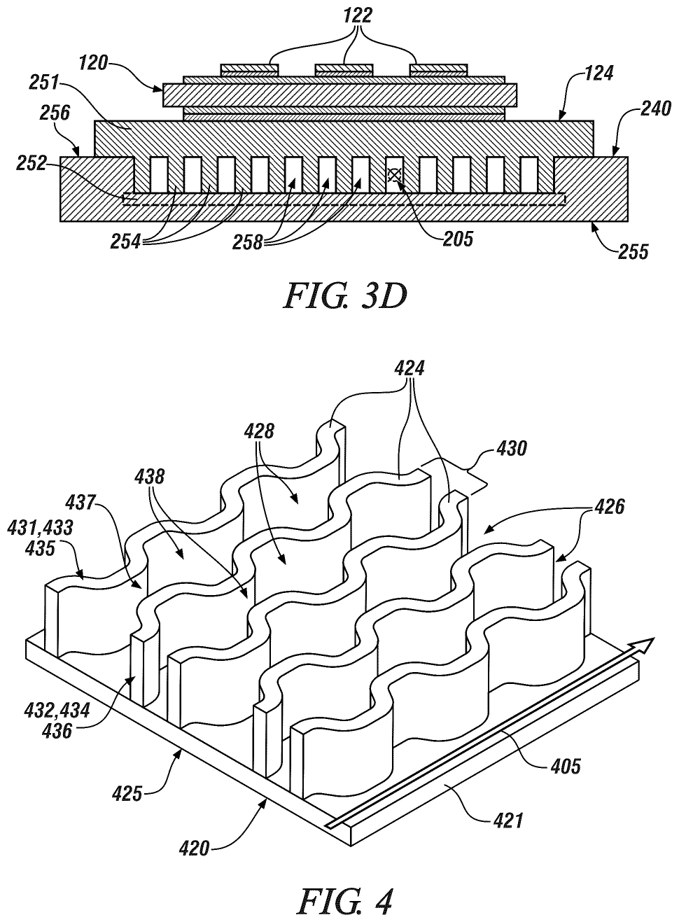

FIG. 3A schematically illustrates a cutaway side view of one of the power modules 120 and an embodiment of the fluidic heat exchanger 220, wherein the side view is defined as being orthogonal to a longitudinal flow axis 205 that is defined by a direction of fluidic flow through the fluidic heat exchanger 220.

The power module 120 is composed of a plurality of power semiconductor switches 122. In one embodiment, the power semiconductor switches 122 are field-effect transistors (FETs). In one embodiment, the FETs are GaN (Gallium Nitride) transistors. In one embodiment, the power semiconductor switches 122 are integrated gate bipolar transistors (IGBTs).

In this embodiment, the power semiconductor switches 122 are coupled to a base plate 124, which is thermally connected to an embodiment of the fluidic heat exchanger 220. In some embodiments, the power module 120 may also be thermally connected to an embodiment of the fluidic heat exchanger 220.

In this embodiment the fluidic heat exchanger 220 includes a first plate portion 221, a second plate portion 222 that is arranged in parallel with the first plate portion 221, and a plurality of flow dividers 224 that are arranged in parallel between a first or inlet end 225 and a second, outlet end 226. The second plate portion 222 does not contact the plurality of flow dividers 224. This arrangement of the first plate portion 221, second plate portion 222 and the plurality of flow dividers 224 creates an open chamber 227 and a plurality of venturi flow channels 228, wherein the plurality of venturi flow channels 228 are arranged in parallel between the first or inlet end 225 and the second or outlet end 226. Additional details related to the plurality of venturi flow channels 228 are described with reference to FIGS. 4, 5, and 6.

FIG. 3B schematically illustrates a sideview of one of the power modules 120 and another embodiment of fluidic heat exchanger 230, wherein the sideview is defined as being orthogonal to a longitudinal axis defined by a direction of fluidic flow through the fluidic heat exchanger 230. The power module 120 is composed of a plurality of power semiconductor switches 122. In this embodiment, the power semiconductor switches 122 are coupled to base plate 124, which is thermally connected to an embodiment of the fluidic heat exchanger 230.

In this embodiment the fluidic heat exchanger 230 includes a first plate portion 231, a second plate portion 232 that is arranged in parallel with the first plate portion 231, and a plurality of flow dividers 234 that are arranged in parallel between a first or inlet end 235 and a second, outlet end 236. The second plate portion 232 is in contact with the plurality of flow dividers 234. This arrangement of the first plate portion 231, second plate portion 232, and the plurality of flow dividers 234 creates a plurality of venturi flow channels 238, wherein the plurality of venturi flow channels 238 are arranged in parallel between the first or inlet end 235 and the second or outlet end 236. Additional details related to the plurality of venturi flow channels 238 are described with reference to FIGS. 4, 5, and 6. In one embodiment, the second plate portion 232 is fabricated from thermally conductive materials. In one embodiment, the second plate portion 232 may be fabricated from thermally insulative materials.

FIG. 3C schematically illustrates a sideview of one of the power modules 120 and an embodiment of fluidic heat exchanger 240, wherein the sideview is defined as being orthogonal to a longitudinal axis defined by a direction of fluidic flow through the fluidic heat exchanger 240. The power module 120 is composed of a plurality of power semiconductor switches 122.

In this embodiment, the power semiconductor switches 122 are thermally connected to an embodiment of the fluidic heat exchanger 240 via base plate 124, which incorporates a first plate portion 241 of the fluidic heat exchanger 240. Stated differently, the fluidic heat exchanger 240 is integrated into power module 120 for heat transfer.

In this embodiment the fluidic heat exchanger 240 includes the first plate 241, a second plate 242 that is arranged in parallel with the first plate 241, and a plurality of flow dividers 244 that are arranged in parallel between a first or inlet end 245 and a second, outlet end 246. The second plate 242 does not contact the plurality of flow dividers 244. This arrangement of the first plate 241, second plate 242 and the plurality of flow dividers 244 creates an open chamber 247 and a plurality of venturi flow channels 248, wherein the plurality of venturi flow channels 248 are arranged in parallel between the first or inlet end 245 and the second or outlet end 246. Additional details related to the plurality of venturi flow channels 248 are described with reference to FIGS. 4, 5, and 6.

FIG. 3D schematically illustrates a sideview of one of the power modules 120 and an embodiment of fluidic heat exchanger 250, wherein the sideview is defined as being orthogonal to a longitudinal axis defined by a direction of fluidic flow through the fluidic heat exchanger 250. The power module 120 is composed of a plurality of power semiconductor switches 122.

In this embodiment, the power semiconductor switches 122 are thermally connected to an embodiment of the fluidic heat exchanger 250. Stated differently, the fluidic heat exchanger 250 is integrated into power module 120 for heat transfer.

In this embodiment the fluidic heat exchanger 250 includes a first plate 251, a second plate 252 that is arranged in parallel with the first plate 251, and a plurality of flow dividers 254 that are arranged in parallel between a first or inlet end 255 and a second, outlet end 256. The second plate 252 is in contact with the plurality of flow dividers 254. This arrangement of the first plate 251, second plate 252 and the plurality of flow dividers 254 creates a plurality of venturi flow channels 258, wherein the plurality of venturi flow channels 258 are arranged in parallel between the first or inlet end 255 and the second or outlet end 256. Additional details related to the plurality of venturi flow channels 258 are described with reference to FIGS. 4, 5, and 6.

FIG. 4 schematically illustrates a portion of an embodiment of fluidic heat exchanger 420, including first plate 421, and a plurality of flow dividers 424 that are arranged in parallel between a first or inlet end 425 and a second, outlet end 426. A plurality of venturi flow channels 428 are formed between the flow dividers 424 and define a longitudinal axis 405. The first plate 421 and the plurality of flow dividers 424 are fabricated from aluminum, copper, or another thermally conductive material.

The first plate 421 is thermally coupled to a heat source, e.g., a solid state power electronic module or device such as described with reference to FIG. 2. The plurality of flow dividers 424 are arranged orthogonal to the first plate 421. The plurality of flow dividers 424 are arranged in parallel with the longitudinal axis 405 between a first end 425 associated with the inlet port and a second end 426 associated with the outlet port. The plurality of flow dividers 424 and the first plate 421 form a plurality of venturi flow channels 428 that are arranged in parallel between the inlet port and the outlet port.

For purposes of explanation, the plurality of flow dividers 424 may be arranged into a plurality of flow divider pairs 430, with each flow divider pair 430 including a first of the plurality of flow dividers 431 and a second of the plurality of flow dividers 432. One of the plurality of flow divider pairs 430 is indicated. The first of the plurality of flow dividers 431 includes a first surface 433 that defines a first waveform 435, wherein the first waveform 435 occurs in relation to the longitudinal axis 405. The second of the plurality of flow dividers 432 includes a second surface 434 that defines a second waveform 436, wherein the second waveform 436 occurs in relation to the longitudinal axis 405. The second surface 434 is symmetrically opposed to the first surface 433 along the longitudinal axis 405. The second surface 434 being symmetrically opposed to the first surface 433 defines a plurality of flow restriction elements 437 and a plurality of expansion chambers 438 in the venturi flow channel 428. The plurality of flow restriction elements 437 and the plurality of expansion chambers 438 are alternatingly arranged in series between the first end 425 and the second end 426.

In this embodiment, the first surface 433 and the second surface 434 are arranged with trapezoidal shapes, such that the first waveform 435 and the second waveform 436 have trapezoidal shapes.

Each of the flow restriction elements 437 arranged in series with the expansion chambers 438 in the venturi flow channel 428 may advantageously generate the Venturi effect during fluidic flow, with an increase in fluid velocity in the flow restriction elements 437, and a decrease in fluid velocity in the expansion chambers 438. This arrangement will facilitate heat transfer between the fluid and the first plate 421 and the plurality of flow dividers 424.

Design considerations include fluid/coolant selection and associated viscosity, flowrate necessary for laminar flow, pressure, and other factors.

This arrangement provides controlled Venturi and laminar coolant flow, which introduces viscous damping to the structure to reduce noise and vibration (NVH) associated with operation of the power module.

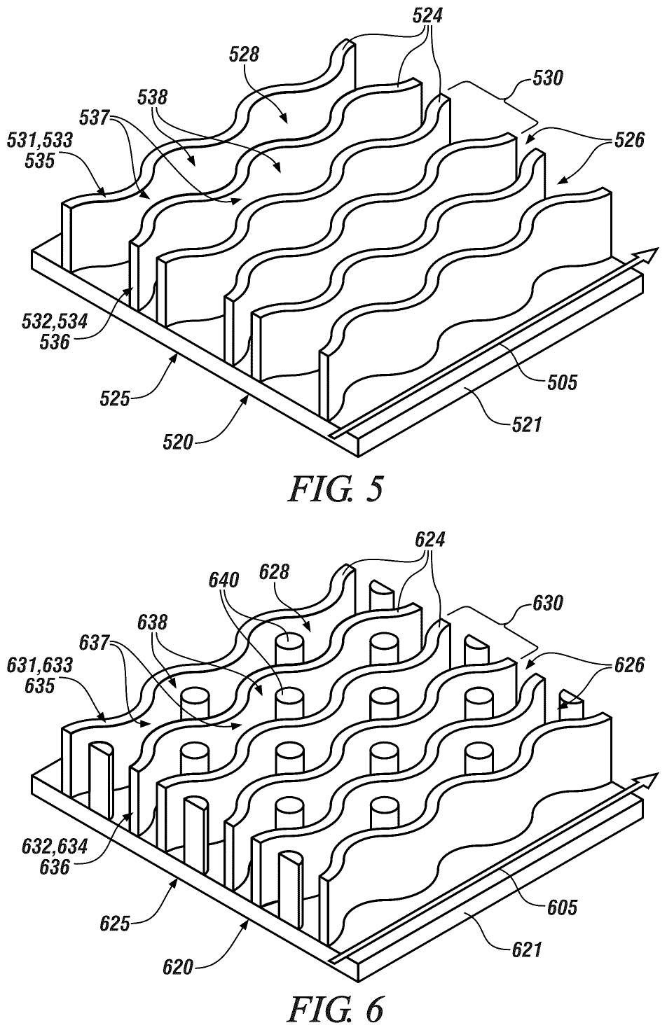

FIG. 5 schematically illustrates details related to an embodiment of fluidic heat exchanger 520, including first plate 521, and a plurality of flow dividers 524 that are arranged in parallel between a first or inlet end 525 and a second, outlet end 526. A plurality of venturi flow channels 528 are formed between the flow dividers 524 and define a longitudinal axis 505.

The first plate 521 is thermally coupled to a heat source, e.g., a solid state power electronic module or device such as described with reference to FIG. 2. The plurality of flow dividers 524 are arranged orthogonal to the first plate 521. The plurality of flow dividers 524 are arranged in parallel with the longitudinal axis 505 between a first end 525 associated with the inlet port and a second end 526 associated with the outlet port. The plurality of flow dividers 524 and the first plate 521 form a plurality of venturi flow channels 528 that are arranged in parallel between the inlet port and the outlet port.

For purposes of explanation, the plurality of flow dividers 524 may be arranged into a plurality of flow divider pairs 530, with each flow divider pair 530 including a first of the plurality of flow dividers 531 and a second of the plurality of flow dividers 532. One of the plurality of flow divider pairs 530 is indicated. The first of the plurality of flow dividers 531 includes a first surface 533 that defines a first waveform 535, wherein the first waveform 535 occurs in relation to the longitudinal axis 505. The second of the plurality of flow dividers 532 includes a second surface 534 that defines a second waveform 536, wherein the second waveform 536 occurs in relation to the longitudinal axis 505. The second surface 534 is symmetrically opposed to the first surface 533 along the longitudinal axis 505. The second surface 534 being symmetrically opposed to the first surface 533 defines a plurality of flow restriction elements 537 and a plurality of expansion chambers 538 in the venturi flow channel 528. The plurality of flow restriction elements 537 and the plurality of expansion chambers 538 are alternatingly arranged in series between the first end 525 and the second end 526.

In this embodiment, the first surface 533 and the second surface 534 are arranged with sinusoidal shapes, such that the first waveform 535 and the second waveform 536 have sinusoidal shapes.

Each of the flow restriction elements 537 arranged in series with the expansion chambers 538 in the venturi flow channel 528 may advantageously generate the Venturi effect during fluidic flow, with an increase in fluid velocity in the flow restriction elements 537, and a decrease in fluid velocity in the expansion chambers 538. This arrangement will facilitate heat transfer between the fluid and the first plate 521 and the plurality of flow dividers 524.

Design considerations include fluid/coolant selection and associated viscosity, flowrate necessary for laminar flow, pressure, and other factors.

This arrangement provides controlled Venturi and laminar coolant flow, which introduces viscous damping to the structure to reduce noise and vibration (NVH) associated with operation of the power module.

FIG. 6 schematically illustrates details related to an embodiment of fluidic heat exchanger 620, including first plate 621, and a plurality of flow dividers 624 that are arranged in parallel between a first or inlet end 625 and a second, outlet end 626. A plurality of venturi flow channels 628 are formed between the flow dividers 624 and define a longitudinal axis 605.

The first plate 621 is thermally coupled to a heat source, e.g., a solid state power electronic module or device such as described with reference to FIG. 2. The plurality of flow dividers 624 are arranged orthogonal to the first plate 621. The plurality of flow dividers 624 are arranged in parallel with the longitudinal axis 605 between a first end 625 associated with the inlet port and a second end 626 associated with the outlet port. The plurality of flow dividers 624 and the first plate 621 form a plurality of venturi flow channels 628 that are arranged in parallel between the inlet port and the outlet port.

For purposes of explanation, the plurality of flow dividers 624 may be arranged into a plurality of flow divider pairs 630, with each flow divider pair 630 including a first of the plurality of flow dividers 631 and a second of the plurality of flow dividers 632. One of the plurality of flow divider pairs 630 is indicated. The first of the plurality of flow dividers 631 includes a first surface 633 that defines a first waveform 635, wherein the first waveform 635 occurs in relation to the longitudinal axis 605. The second of the plurality of flow dividers 632 includes a second surface 634 that defines a second waveform 636, wherein the second waveform 636 occurs in relation to the longitudinal axis 605. The second surface 634 is symmetrically opposed to the first surface 633 along the longitudinal axis 605. The second surface 634 being symmetrically opposed to the first surface 633 defines a plurality of flow restriction elements 637 and a plurality of expansion chambers 638 in the venturi flow channel 628. The plurality of flow restriction elements 637 and the plurality of expansion chambers 638 are alternatingly arranged in series between the first end 625 and the second end 626.

In this embodiment, the first surface 633 and the second surface 634 are arranged with sinusoidal shapes, such that the first waveform 635 and the second waveform 636 have sinusoidal shapes. In addition, a plurality of pins 640 are arranged in the plurality of expansion chambers 638, with each of the pins 640 being affixed to and thermally coupled to the first plate 621, and projecting orthogonally therefrom. In one embodiment, and as shown, each pin 640 is a cylinder, with a cross-section that is arranged to maximize heat transfer with the fluid, and also to introduce fluidic constraints to advantageously transfer heat within the respective expansion chamber 638.

Alternatively, each pin 640 may have a frustoconical shape to increase surface area. Alternatively, each pin 640 may have a teardrop cross-sectional shape to interact with and form fluidic flow therearound, wherein the cross-sectional shape facilitates or otherwise enables laminar flow. Alternatively, each pin 640 may have another cross-sectional shape, such as conical, teardrop, serrated, etc., to increase surface area and/or to channel and/or interact with and form fluidic flow therearound. This includes each pin 640 having a cross-sectional shape that facilitates or otherwise enables laminar flow under pre-defined and achievable flow conditions.

Each of the flow restriction elements 637 arranged in series with the expansion chambers 638 in the venturi flow channel 628 may advantageously generate the Venturi effect during fluidic flow, with an increase in fluid velocity in the flow restriction elements 637, and a decrease in fluid velocity in the expansion chambers 638. This arrangement will facilitate heat transfer between the fluid and the first plate 621 and the plurality of flow dividers 624.

Design considerations include fluid/coolant selection and associated viscosity, flowrate necessary for laminar flow, pressure, and other factors.

This arrangement provides controlled Venturi and laminar coolant flow, which introduces viscous damping to the structure to reduce noise and vibration (NVH) associated with operation of the power module. NVH damping may be enhanced by controlling viscosity of the cooling fluid, design and placement of the pins 640, and/or flow design tuning that minimizes resonance.

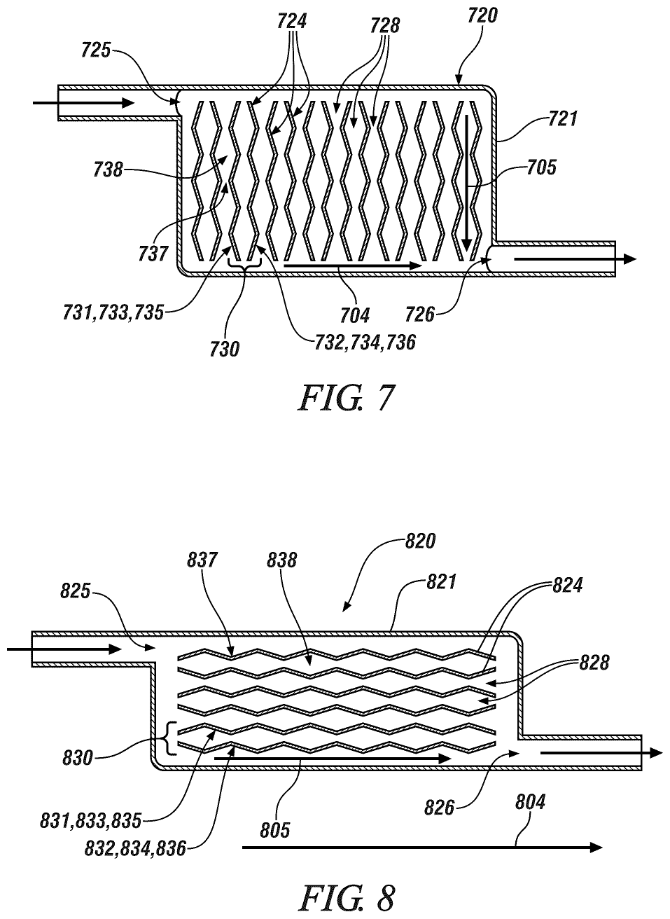

FIG. 7 schematically illustrates a cutaway top or plan view of an embodiment of fluidic heat exchanger 720, including a plurality of flow dividers 724 affixed to first plate 721, and arranged in parallel between a first or inlet end 725 and a second, outlet end 726. A plurality of venturi flow channels 728 are formed between the flow dividers 724 and define a transverse flow axis 705, which is transverse to a longitudinal axis 704 defined between the first or inlet end 725 and the second, outlet end 726.

The plurality of flow dividers 724 may be arranged into a plurality of flow divider pairs 730, with each flow divider pair 730 including a first of the plurality of flow dividers 731 and a second of the plurality of flow dividers 732. The first of the plurality of flow dividers 731 includes a first surface 733 that defines a first waveform 735, wherein the first waveform 735 occurs in relation to the longitudinal axis 705. The second of the plurality of flow dividers 732 includes a second surface 734 that defines a second waveform 736, wherein the second waveform 736 occurs in relation to the longitudinal axis 705. The second surface 734 is symmetrically opposed to the first surface 733 along the longitudinal axis 705. The second surface 734 being symmetrically opposed to the first surface 733 defines a plurality of flow restriction elements 737 and a plurality of expansion chambers 738 in the venturi flow channel 728. The plurality of flow restriction elements 737 and the plurality of expansion chambers 738 are alternatingly arranged in series between the first end 725 and the second end 726.

FIG. 8 schematically illustrates a cutaway top or plan view of an embodiment of the fluidic heat exchanger 820, including a plurality of flow dividers 824 affixed to first plate 821, and arranged in parallel between a first or inlet end 825 and a second, outlet end 826. A plurality of venturi flow channels 828 are formed between the flow dividers 824 and define a longitudinal flow axis 805, which is parallel to a longitudinal axis 804 defined between the first or inlet end 825 and the second, outlet end 826.

The plurality of flow dividers 824 may be arranged into a plurality of flow divider pairs 830, with each flow divider pair 830 including a first of the plurality of flow dividers 831 and a second of the plurality of flow dividers 832. The first of the plurality of flow dividers 831 includes a first surface 833 that defines a first waveform 835, wherein the first waveform 835 occurs in relation to the longitudinal flow axis 805. The second of the plurality of flow dividers 832 includes a second surface 834 that defines a second waveform 836, wherein the second waveform 836 occurs in relation to the longitudinal flow axis 805. The second surface 834 is symmetrically opposed to the first surface 833 along the longitudinal flow axis 805. The second surface 834 being symmetrically opposed to the first surface 833 defines a plurality of flow restriction elements 837 and a plurality of expansion chambers 838 in the venturi flow channel 828. The plurality of flow restriction elements 837 and the plurality of expansion chambers 838 are alternatingly arranged in series between the first end 825 and the second end 826.

This arrangement of a fluidic heat exchanger having a plurality of flow dividers that form a plurality of venturi flow channels enable Venturi-effect cooling in an area that is adjacent to and thermally coupled to a heat generation area, e.g., a solid state electronic power module, and may result in reduced thermal resistance, reduced pumping pressure drop and loss. The symmetric structure also facilitates manufacturability. It allows installing the power modules on both sides to reduce system size and increase power density, beneficial for multilevel inverter which has high switch count. It also facilitates laminar coolant flow to increase thermal conductivity and pumping efficiency.

Designs of the Venturi channels and pins may include contoured arrangements, conical arrangements, oval arrangements, etc. that are optimized for temperature/pressure differences at inlet locations and/or outlet locations.

Furthermore, the controlled Venturi and laminar coolant flow adds viscous damping to the structure which improves inverter NVH performance.

Furthermore, the arrangement is applicable for single, dual, or multilevel inverters/converters and other cooling applications.

The detailed description and the drawings or figures are supportive and descriptive of the present teachings, but the scope of the present teachings is defined solely by the claims. While some of the best modes and other embodiments for carrying out the present teachings have been described in detail, various alternative designs and embodiments exist for practicing the present teachings defined in the appended claims.

What is claimed is:

1. A fluidic heat exchanger, comprising:
a first plate, a second plate, an inlet port, an outlet port, and a plurality of flow dividers;
wherein the first plate is thermally couplable to a heat source;
wherein the plurality of flow dividers are arranged orthogonal to the first plate and are arranged orthogonal to the second plate;
wherein the plurality of flow dividers are arranged in parallel between the inlet port and the outlet port;
wherein the plurality of flow dividers, the first plate, and the second plate form a plurality of venturi flow channels that are arranged in parallel between the inlet port and the outlet port;
wherein the plurality of flow dividers are arranged into a plurality of flow divider pairs, each flow divider pair including a first of the plurality of flow dividers and a second of the plurality of flow dividers;
wherein the first of the plurality of flow dividers includes a first surface defining a first waveform;
wherein the second of the plurality of flow dividers includes a second surface defining a second waveform;
wherein the second surface is symmetrically opposed to the first surface along a longitudinal axis defined between the inlet port and the outlet port;
wherein the second surface being symmetrically opposed to the first surface defines a plurality of flow restriction elements and a plurality of expansion chambers in the venturi flow channel; and
wherein the plurality of flow restriction elements and the plurality of expansion chambers are alternatingly arranged in series between the inlet port and the outlet port.

2. The fluidic heat exchanger of claim 1, further comprising a plurality of pins being affixed to and projecting orthogonally from the first plate, wherein the plurality of pins are disposed in the plurality of expansion chambers.

3. The fluidic heat exchanger of claim 2, wherein each of the plurality of pins is cylindrically-shaped.

4. The fluidic heat exchanger of claim 2, wherein each of the plurality of pins has a frustoconical shape.

5. The fluidic heat exchanger of claim 2, wherein each of the plurality of pins is fabricated from a thermally conductive material.

6. The fluidic heat exchanger of claim 2, further comprising the plurality of pins being affixed to the second plate.

7. The fluidic heat exchanger of claim 1, wherein the first waveform defined by the first of the plurality of flow dividers comprises a sinusoidal waveform, and the second waveform defined by the second of the plurality of flow dividers comprises a sinusoidal waveform.

8. The fluidic heat exchanger of claim 1, wherein the first waveform defined by the first of the plurality of flow dividers comprises a trapezoidal waveform, and the second waveform defined by the second of the plurality of flow dividers comprises a trapezoidal waveform.

9. The fluidic heat exchanger of claim 1, wherein the first plate is formed from a thermally conductive material.

10. The fluidic heat exchanger of claim 1, wherein the second plate is fabricated from a thermally conductive material.

11. The fluidic heat exchanger of claim 1, wherein the second plate is fabricated from a thermally insulative material.

12. The fluidic heat exchanger of claim 1, wherein each of the plurality of flow dividers is fabricated from a thermally conductive material.

13. The fluidic heat exchanger of claim 1, further comprising the plurality of flow dividers being arranged in parallel and in parallel to a longitudinal axis defined between the inlet port and the outlet port.

14. The fluidic heat exchanger of claim 1, further comprising the plurality of flow dividers being arranged in parallel and arranged transverse to a longitudinal axis defined between the inlet port and the outlet port.

15. A cooling system for a solid state electronic power module, comprising:
a fluidic circuit including a fluidic heat exchanger, a pump, a radiator, and a sump, wherein the fluidic circuit contains a heat transfer fluid;
wherein the fluidic heat exchanger includes a first plate, an inlet port, an outlet port, and a plurality of flow dividers;
wherein the first plate is thermally coupled to the solid state electronic power module;
wherein the plurality of flow dividers are arranged orthogonal to the first plate;
wherein the plurality of flow dividers are arranged in parallel between the inlet port and the outlet port;
wherein the plurality of flow dividers and the first plate form a plurality of venturi flow channels that are arranged in parallel between the inlet port and the outlet port;
wherein the plurality of flow dividers are arranged into a plurality of flow divider pairs, each flow divider pair including a first of the plurality of flow dividers and a second of the plurality of flow dividers;
wherein the first of the plurality of flow dividers includes a first surface defining a first waveform;
wherein the second of the plurality of flow dividers includes a second surface defining a second waveform;
wherein the second surface is symmetrically opposed to the first surface along a longitudinal axis defined between the inlet port and the outlet port;
wherein the second surface being symmetrically opposed to the first surface defines a plurality of flow restriction elements and a plurality of expansion chambers in the venturi flow channel; and
wherein the plurality of flow restriction elements and the plurality of expansion chambers are alternatingly arranged in series between the inlet port and the outlet port.

16. The cooling system of claim 15, further comprising a plurality of pins being affixed to and projecting orthogonally from the first plate, wherein the plurality of pins are disposed in the plurality of expansion chambers.

17. The cooling system of claim 15, wherein the first waveform defined by the first flow divider comprises a sinusoidal waveform, and the second waveform defined by the second waveform comprises a sinusoidal waveform.

18. The cooling system of claim 15, wherein the first waveform defined by the first flow divider comprises a trapezoidal waveform, and the second waveform defined by the second flow divider comprises a trapezoidal waveform.

19. The cooling system of claim 15, wherein the first plate is formed from a thermally conductive material.

20. An electrified drivetrain for a vehicle, comprising:
a DC power source, a multi-phase power inverter, a multi-phase rotary electric machine, a torque actuator, and a cooling system;
wherein the multi-phase power inverter includes a solid state electronic power module;
a fluidic circuit including a fluidic heat exchanger, a pump, a radiator, and a sump, wherein the fluidic circuit contains a heat transfer fluid;
wherein the fluidic heat exchanger includes a first plate, a second plate, an inlet port, an outlet port, and a plurality of flow dividers;
wherein the first plate is thermally coupled to the solid state electronic power module;
wherein the plurality of flow dividers are arranged orthogonal to the first plate and are arranged orthogonal to the second plate;
wherein the plurality of flow dividers are arranged in parallel between the inlet port and the outlet port;
wherein the plurality of flow dividers, the first plate, and the second plate form a plurality of venturi flow channels that are arranged in parallel between the inlet port and the outlet port;
wherein the plurality of flow dividers are arranged into a plurality of flow divider pairs, each flow divider pair including a first of the plurality of flow dividers and a second of the plurality of flow dividers;
wherein the first of the plurality of flow dividers includes a first surface defining a first waveform;
wherein the second of the plurality of flow dividers includes a second surface defining a second waveform;
wherein the second surface is symmetrically opposed to the first surface along a longitudinal axis defined between the inlet port and the outlet port;
wherein the second surface being symmetrically opposed to the first surface defines a plurality of flow restriction elements and a plurality of expansion chambers in the venturi flow channel; and
wherein the plurality of flow restriction elements and the plurality of expansion chambers are alternatingly arranged in series between the inlet port and the outlet port.
